(19) United States
(12) Patent Application Publication
(10) Pub. No.: US 2021/0253858 A1
(43) Pub. Date: Aug. 19, 2021

(54) CURABLE ORGANOPOLYSILOXANE COMPOSITION, ENCAPSULANT, AND SEMICONDUCTOR DEVICE

(71) Applicant: WACKER CHEMIE AG, Munich (DE)

(72) Inventors: HongJeong YU, Seongnam-si (KR); YoungJin KIM, Seongnam-si (KR); Arvid KUHN, Burghausen (DE); GyeongHui LEE, Seongnam-si (KR); HyunKwan YANG, Seongnam-si (KR)

(73) Assignee: WACKER CHEMIE AG, Munich (DE)

(21) Appl. No.: 17/268,992

(22) PCT Filed: Aug. 31, 2018
(86) PCT No.: PCT/EP2018/073483

§ 371 Date: Feb. 17, 2021

(51) Int. Cl. C08L 83/04; C09D 183/04; H01L 33/56; H01L 23/29

(52) U.S. Cl. CPC C08L 83/04; C09D 183/04; C08L 2205/025; H01L 23/296; H01L 33/56

(57) ABSTRACT

A curable organopolysiloxane composition, a Light Emitting Diode (LED) encapsulant and a semiconductor device, wherein the curable organopolysiloxane composition contains units of the formula 1

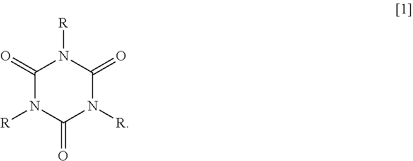

### CROSS REFERENCE TO RELATED APPLICATIONS

This application is the U.S. National Phase of PCT Appln. No. PCT/EP2018/073483 filed Aug. 31, 2018, the disclosure of which is incorporated in its entirety by reference herein.

### BACKGROUND OF THE INVENTION

### 1. Field of the Invention

The present invention relates to a curable organopolysiloxane composition, a Light Emitting Diode (LED) encapsulant and a semiconductor device comprising the encapsulant.

### 2. Description of the Related Art

Light emitting devices such as light emitting diodes (LED), organic light emitting diodes (OLED) device and a photoluminescence devices (PL devices) have been used for home appliances, lighting devices, display devices, and various kinds of automation devices.

The light emitting device can display the intrinsic color of the light emitting material, such as blue, red and green in the light emitting portion, and can display white by combination of the colors.

An encapsulant basically serves to protect a light emitting device from external contaminants such as moisture and gas, in particular, sulfur, and allows light to pass through the light emitting device and to emit light outside the device. When a light emitting device having metal is exposed to external contaminants, the contaminants generally penetrate into the device through the encapsulant, the metal is rusted and its color is changed. It leads to the reduction of the luminance and optical transmittance of the light emitting device. Accordingly, it is important to effectively protect from gas and moisture, which are external contaminants, and to prevent discoloration.

Further, in order to protect the light emitting device from external shock, the encapsulants should have a physical hardness to some extent. Such increase of hardness affects blockage of gas, which contributes to increase in reliability (resistance to color and chemical), which is an important physical property.

As a basic material for the LED encapsulant, curable silicone compositions and curable epoxy compositions have been used. Particularly, the silicone compositions curable by the hydrosilylation, which gives optically clear silicone products, have been mainly used for good properties such as resistance to heat, moisture, and light.

U.S. Pat. No. 7,527,871 discloses a curable organopolysiloxane composition comprising (A) a linear organopolysiloxane having at least two alkenyl groups and at least one aryl group, (B) a branched organopolysiloxane, having at least one alkenyl group and aryl group, (C) a linear organopolysiloxane, with terminal Si—H, containing at least one aryl group, and (D) a hydrosilylation reaction catalyst.

U.S. Pat. No. 8,258,502 teaches a composition comprising (I) an alkenyl functional phenyl-containing polyorganosiloxane, (II) a hydrogendiorganosiloxy terminated oligodiphenylsiloxane, and (III) a hydrosilylation catalyst.

U.S. Pat. No. 9,306,133 also discloses a curable silicone resin composition for an optical semiconductor device, comprising: (A) an aryl group and an alkenyl group-containing organopolysiloxane; (B) organohydrogenpolysiloxane having at least two hydrosilyl groups (SiH groups) per molecule and also having an aryl group, in a constituent unit having an amount such that a molar ratio of the hydrosilyl group in component (B) with respect to the alkenyl group in component (A) (SiH group/alkenyl group) is 0.70 to 1.00; and (C) a hydrosilylation catalyst.

Unfortunately, the curable organopolysiloxane compositions in the prior art still have problems such as unsatisfactory hardness and poor resistance to gas or water. The compositions described in the prior art often show an increase in hardness after curing during storage at high temperature. Due to the change in hardness and weight loss, the materials are not stable under normal operating conditions.

The conventional hydrosilylation curable silicone encapsulants have increased the hardness through curing with heat by comprising an organosilicone having a T structure. The hardness could be affected by the content of the T structure. However, simply increasing the content of the T structure raises the coefficient of thermal expansion (CTE), which causes a problem that a large number of cracks occur in the encapsulant while undergoing the curing process. Furthermore, it has been known that the moisture and gas barrier effect is not so great when considering the improvement in the hardness. In addition, since the T-structure organosilicone composition has high viscosity, the time required for the mixing process increases, and a higher pressure is required in the coating process. Accordingly, there has been a demand for encapsulants without those problems.

An object of the present invention is to provide a curable organopolysiloxane composition with excellent hardness, and blocking effect against gas and moisture, an LED encapsulant and a semiconductor device.

### SUMMARY OF THE INVENTION

The curable organopolysiloxane composition according to the present invention comprises:

(A) a compound represented by formula 1 as below and having molecular weight less than 500,

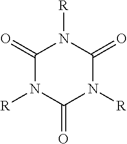

(B) a siloxane compound comprising Si—H, and

(C) a polysiloxane compound comprising Si-bonded alkenyl group,

wherein R represents hydrogen, substituted or unsubstituted C1 to C20 alkyl, substituted or unsubstituted C7 to C20 arylalkyl, substituted or unsubstituted C1 to C20 heteroalkyl, substituted or unsubstituted C3 to C12 cycloalkyl, substituted or unsubstituted C2 to C20 heterocycloalkyl, substituted or unsubstituted C2 to C20 alkenyl, substituted or unsubstituted C2 to C20 alkynyl, substituted or unsubstituted C6 to C30 aryl, substituted or unsubstituted C1 to C10 alkoxy, substituted or unsubstituted C1 to C30 acyl, hydroxy, halogen, or a combination thereof, provided that at least one of R is substituted or unsubstituted C2 to C20 alkenyl.

The curable organopolysiloxane composition may further comprise (D) a hydrosilylation catalyst comprising a platinum group metal.

### BRIEF DESCRIPTION OF THE DRAWINGS

FIG. 1 represents one embodiment of the crosslinked structure of the curable organopolysiloxane composition according to the present invention.

### DETAILED DESCRIPTION OF THE PREFERRED EMBODIMENTS

A cured product of the present invention is obtained by curing the above-described curable organopolysiloxane composition.

An LED encapsulant of the present invention comprises the above-described curable organopolysiloxane composition.

Furthermore, the semiconductor device of the present invention comprises semiconductor elements that are coated with a cured product of the above-described curable organopolysiloxane composition.

The curable organopolysiloxane composition according to the present invention provides excellent mechanical properties such as high hardness, low water/gas permeability than the conventional siloxane compositions, and an increased bonding strength.

In addition, the composition exhibits low modulus at a high temperature while maintaining the same hardness, and has a low thermal expansion coefficient, thereby reducing crack or releasing at high temperature curing to improve high temperature thermal shock resistance.

When the composition is used as an encapsulant for sealing a light emitting device such as an LED, the problem of reducing the optical characteristics of the LED due to external exposure for a long time can be solved. The product provides low water/gas permeability, which is helpful for reduction of discoloration of substrate of LED package due to sulfur transfer. Discoloration of the encapsulant will not occur, and thus, the luminance reduction of the LED package will be small. It is suitable for forming a cured product having a high refractive index and a high light transmittance.

Hereinafter, an exemplary embodiment of the present invention will be described in detail. However, the exemplary embodiment may be modified in various forms, and the scope of the present invention is not limited to the exemplary embodiment.

The present invention provides a curable organopolysiloxane composition comprising:

(A) a compound represented by formula 1 as below and having molecular weight less than 500,

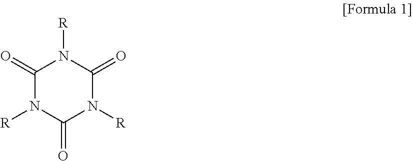

(B) a siloxane compound comprising Si—H, and

(C) a polysiloxane compound comprising Si-bonded alkenyl group, wherein R represents hydrogen, substituted or unsubstituted C1 to C20 alkyl, substituted or unsubstituted C7 to C20 arylalkyl, substituted or unsubstituted C1 to C20 heteroalkyl, substituted or unsubstituted C3 to C12 cycloalkyl, substituted or unsubstituted C2 to C20 heterocycloalkyl, substituted or unsubstituted C2 to C20 alkenyl, substituted or unsubstituted C2 to C20 alkynyl, substituted or unsubstituted C6 to C30 aryl, substituted or unsubstituted C1 to C10 alkoxy, substituted or unsubstituted C1 to C30 acyl, hydroxy, halogen, or a combination thereof, provided that at least one of R is substituted or unsubstituted C2 to C20 alkenyl.

Hereinafter, each component will be described in detail.

Hereinafter “the total amount of the composition” refers to sum of the contents of each components constituting the composition, except for catalysts, component (D). For example, it can refer to the sum of the contents of components (A), (B) and (C), or the sum of the contents of components (A), (B), (C), and other optional components such as an adhesion promoter.

### Component (A)

Component (A) is a compound represented by formula 1 as shown below:

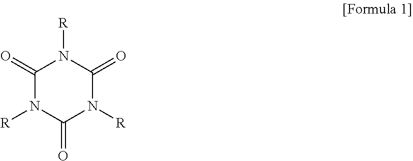

wherein R represents hydrogen, substituted or unsubstituted C1 to C20 alkyl, substituted or unsubstituted C7 to C20 arylalkyl, substituted or unsubstituted C1 to C20 heteroalkyl, substituted or unsubstituted C3 to C12 cycloalkyl, substituted or unsubstituted C2 to C20 heterocycloalkyl, substituted or unsubstituted C2 to C20 alkenyl, substituted or unsubstituted C2 to C20 alkynyl, substituted or unsubstituted C6 to C30 aryl, substituted or unsubstituted C1 to C10 alkoxy, substituted or unsubstituted C1 to C30 acyl, hydroxy, halogen, or a combination thereof, provided that at least one of R is substituted or unsubstituted C2 to C20 alkenyl. At least two R's are preferably substituted or unsubstituted C2 to C20 alkenyl, more preferably substituted or unsubstituted C2 to C6 alkenyl. Particularly, it is preferable that two R's are substituted or unsubstituted C2 to C6 alkenyl and one R is a halogen-substituted C1 to C6 alkyl or a substituted or unsubstituted C7 to C20 arylalkyl, or that three R's are substituted or unsubstituted C2 to C6 alkenyl.

Unsubstituted alkenyl is preferable to substituted alkenyl in consideration of steric hinderance. This is because steric hinderance from a substitutent may cause a reaction delay.

As shown in formula 1, the compound having nitrogen atom as a ring member is preferable to that having a silicon atom as a ring member. This is because amide bonding (nitrogen-carbon bonding) may easily react with air contaminants (ex. sulfur) and thus, may easily absorb the contaminants.

Component (A) may function as sulfur scavenger.

Component (A) has molecular weight less than 500, preferably 200 to 300.

Component (A) is preferably present in an amount of 1 to 20% by weight, more preferably, 2 to 10% by weight, most preferably, 3 to 8% by weight, based on the total amount of the composition. When the content of component (A) is below the lower limit of the above-mentioned range, the present composition tends to fail to achieve complete cured body. When it exceeds the upper limit of the above-mentioned range, hardness may be lowered, which makes it inappropriate to be used as LED encapsulant.

The curable organopolysiloxane composition according to an exemplary embodiment of the present invention contains the isocyanurate ring part as component (A) in the main chain, unlike the conventional siloxane compositions, and thus may form a more dense structure.

As a result, the composition may give excellent mechanical properties such as high hardness and low gas permeation. In addition, the composition may exhibit low modulus at a high temperature while maintaining the same hardness, and has a low thermal expansion coefficient, thereby reducing crack or stress releasing at high temperature curing to improve high temperature thermal shock resistance.

Based on component (A), it is possible to provide high hardness without changing the content of the T-structure organosilicone compound in the composition, and at the same time, the water/gas permeation reducing effect can be improved.

Further, the composition according to an exemplary embodiment of the present invention may or may not include inorganic filler.

### Component (B)

Component (B) is a curing agent.

Component (B) is a siloxane compound comprising Si—H. Preferably, component (B) can be a single molecule siloxane or siloxane oligomer or organopolysiloxane, which has one or more hydrosilyl group (Si—H) in its molecular, but has no aliphatic unsaturated group. Therefore, component (B) proceeds hydrosilylation with the component having alkenyl group (for example, component (A)).

By comprising component (B) in the curable silicone resin composition, curing reaction by the hydrosilylation may proceed effectively. Its cured product also exhibits excellent sulfur barrier properties.

The number of hydrosilyl groups contained in component (B) is not particularly limited, but is preferably 2 or more (for example, 2 to 50) in view of the curability of the curable organopolysiloxane composition.

Examples of component (B) include a single molecule siloxane or siloxane oligomer or an organopolysiloxane or an organopolysiloxysilylalkylene wherein the siloxane has at least one, preferably two or more hydrosilyl groups in the molecule.

Further, component (B) has no aliphatic unsaturated group in the molecule as described above. The aliphatic unsaturated group is an aliphatic hydrocarbon group having a non-aromatic carbon-carbon unsaturated bond, and examples thereof include an ethylenic unsaturated group and an acetylenic unsaturated group. Examples of the ethylenic unsaturated group include an alkenyl group such as a vinyl group, an allyl group, a propenyl group, a butenyl group and a 5-hexenyl group (for example, a C2-20 alkenyl group (particularly, a C2-10 alkenyl group); an alkadienyl group such as a 1, 3-butadienyl group (particularly, a C4-10 alkadienyl group); alkenylcarbonyloxy groups such as acryloyloxy group and methacryloyloxy group; and an alkenylcarbonylamino group such as an acrylamide group. Examples of the acetylenic unsaturated group include an alkynyl group such as an ethynyl group and a propargyl group (for example, a C2-20 alkynyl group (particularly, a C2-10 alkynyl group)); an alkynylcarbonyloxy group such as an ethynylcarbonyloxy group; and an alkynylcarbonylamino group such as an ethynylcarbonylamino group.

Preferably, component (B) is a single molecule siloxane or siloxane oligomer or organopolysiloxane without any silalkylene bond in the main chain. Examples of the siloxane material include those having a molecular structure of straight chain and branched chain (linear chain having some branches, branched chain, and mesh chain). The siloxane material may be used alone or in combination of two or more. For example, two or more organopolysiloxanes having different molecular structures can be used in combination. A linear organopolysiloxane and a branched organopolysiloxane may be used in combination.

Among the groups bonded to the silicon atom of the organopolysiloxane, the groups other than the hydrogen atoms are not particularly limited, and examples thereof include monovalent substituted or unsubstituted hydrocarbon groups, but exclude aliphatic unsaturated groups. Specifically the examples include an alkyl group, an aryl group, an aralkyl group, and a halogenated hydrocarbon group. An alkyl group and an aryl group are preferable. A methyl group and a phenyl group are particularly preferable.

The siloxane material may be in a liquid state or in a solid state at 25° C., preferably, in a liquid state. It is more preferable that the liquid has a viscosity of 1 to 100,000 mPa·s at 25° C.

The organopolysiloxane represented by the average unit formula

(R¹₃SiO_{3/2})ₐ₁(R¹₂SiO_{2/2})_{b1}(R¹SiO_{1/2})_{c1}(SiO_{4/2})_{d1}(XO_{1/2})ₑ₁

is preferable.

In the average unit formula, each of R¹ is the same as or different from each other, and is a substituted or unsubstituted monovalent hydrocarbon group except for aliphatic unsaturated group. Examples of R¹ comprise a hydrogen atom, an alkyl group, an aryl group, an aralkyl group, and a halogenated alkyl group, provided that at least a part of R¹ is a hydrogen atom (a hydrogen atom constituting a hydrosilyl group) so that there is one or more, preferably, two or more hydrosilyl groups in the molecule. For example, the amount of hydrogen atoms is preferably 1 to 40 mol %, based on the total amount of R¹ (100 mol %). By controlling the ratio within the above range, the curability of the curable organopolysiloxane composition tends to be further improved. As the R¹ other than the hydrogen atom, an alkyl group (especially, a methyl group) and an aryl group (especially, a phenyl group) are preferable.

In the above average unit formula, X is a hydrogen atom or an alkyl group similarly to the above. As the alkyl group, a methyl group, an ethyl group, a propyl group, a butyl group, a pentyl group, and a hexyl group are exemplified, and the methyl group is particularly preferable.

Each of a1, b1, c1, d1, and e1 is the same or different from each other, and is 0 or a positive number; and (a1+b1+c1) is a positive number.

An example of organopolysiloxane may include a linear organopolysiloxane having at least one (preferably, two or more) hydrosilyl groups in the molecule. As the group bonded to the silicon atom other than the hydrogen atom in the linear organopolysiloxane, for example, the monovalent substituted or unsubstituted hydrocarbon group described above (but, the aliphatic unsaturated group is excluded) can be used. An alkyl group, especially, a methyl group, and an aryl group, especially, a phenyl group, are particularly preferable.

Preferably, component (B) is a single molecule siloxane or siloxane oligomer or linear organopolysiloxane with both terminal ends of the molecular chain blocked by silicon bonded hydrogen atoms having at least one silicon bonded aryl group per molecule. By using such siloxane material as a curing agent, instead of a branched organopolysiolxane, a good elongation performance may be obtained.

The content of hydrogen atoms (bonded to silicon atoms) in the siloxane material is not particularly limited, but is preferably 0.1 to 40 mol %, based on the total amount of groups bonded to silicon atoms (100 mol %). The content of the alkyl group, particularly methyl group is not particularly limited, but is preferably from 20 to 99 mol %, based on the total amount of the groups bonded to silicon atoms (100 mol %). The content of the aryl group, particularly phenyl group is not particularly limited, but is preferably 5 to 60 mol %, based on the total amount of the groups bonded to the silicon atom (100 mol %). Particularly, it is preferable that the content of the aryl group, particularly phenyl group as the siloxane material is 5 mol % or more, for example, 5 to 50 mol %, based on the total amount of the silicon atom-bonded groups (100 mol %).

Particularly, by using the siloxane material having a proportion of an aryl group, particularly phenyl group, of not less than 10 mol %, for example, 10 to 40 mol %, with respect to the total amount of groups bonded to silicon atoms (100 mol %), the sulfur barrier property of the cured product tends to be further improved. Further, by using a siloxane material having a content of an alkyl group, in particular, a methyl group, of 30 mol % or more, for example, 40 to 70 mol %, based on a total amount of a group bonded to a silicon atom (100 mol %), the thermal shock resistance of the cured product tends to be further improved.

Preferably, the siloxane material represented by formula 2 as below may be used.

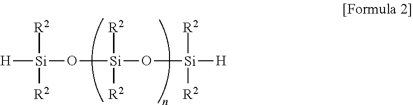

where R² is the same as or different from each other and a hydrogen atom or a substituted or unsubstituted monovalent hydrocarbon group with the exception of unsaturated groups, preferably, alkenyl groups. At least one of R² is a hydrogen atom and n is an integer of 1 or more. At least one R² is preferably an aryl group.

Examples of the monovalent hydrocarbon groups of R² include the above-mentioned alkyl groups, the above-mentioned aryl groups, and the above-mentioned halogenated alkyl groups. Here, at least one R² per molecule must be one of the above-mentioned aryl groups, preferably, phenyl.

In addition, n is an integer of 1 or more, preferably, an integer in the range of from 1 to 20, and, especially preferably, an integer in the range of from 1 to 10. This is due to the fact that when the value of n exceeds the upper limit of the above-mentioned range, the filling properties of the resultant composition, or the adhesive properties of the cured product tend to deteriorate. It is most preferable that n is 1 to 4.

In addition, examples of silicon bonded organic groups of component (B) other than the aryl groups include substituted or unsubstituted monovalent hydrocarbon groups with the exception of alkenyl groups, such as the above-described alkyl groups, the above-described aralkyl groups, and the above-described halogenated alkyl groups, with methyl being particularly preferable.

It is preferable that the content of the silicon bonded aryl groups in component (B) is not less than 5 mol % and, particularly preferably, not less than 10 mol %, based on all the silicon bonded organic groups. Although there are no limitations, the viscosity of component (B) at 25° C. is preferable in the range of from 1 to 1,000 mPa·s, especially preferable, in the range of from 2 to 500 mPa·s. This is due to the fact that when the viscosity of component (B) is below the lower limit of the above-mentioned range, it may tend to volatilize and the makeup of the resultant composition may be unstable, and, on the other hand, when it exceeds the upper limit of the above-mentioned range, the handling properties of the resultant composition tend to deteriorate.

By having M unit as the repeating unit, instead of Q or T unit, a good elongation performance may be obtained.

Component (B) is present in an amount of 10 to 50% by weight, preferably, 15 to 30% by weight, based on the total amount of the composition.

It is preferable that a molar ratio of Si—H group to component (B)/alkenyl group, for example, vinyl group, in components (A) and (C) is 0.8 to 1.2 to reduce the reactive residual silicone hydride.

### Component (C)

Component (C) represents a polysiloxane compound comprising Si-bonded alkenyl group. Component (C) is preferably a branched organopolysiloxane having at least one alkenyl group in the molecule. In the curable organopolysiloxane composition, component (C) is such a component that generates a hydrosilylation with component (B), along with component (A).

Component (C) is used to impart strength to the cured product obtained by curing the composition. Specifically, when the curable organopolysiloxane composition contains component (C), the heat resistance, thermal shock resistance and sulfur barrier property of the cured product may be further improved.

Component (C) is preferably a branched organopolysiloxane having at least one alkenyl group in the molecule and having —Si—O—Si— (siloxane bond) as a main chain and no silalkylene bond. Component (C) also includes an organopolysiloxane having a three-dimensional structure such as a net shape.

In component (C), the alkenyl group may be a substituted or unsubstituted alkenyl group. The examples of the alkenyl groups include vinyl, allyl, butenyl, pentenyl, and hexenyl group, preferably vinyl group. The number of alkenyl groups contained in the molecule of component (C) is not particularly limited, but is 1 or more, preferably 2 or more (for example, 2 to 50) from the viewpoint of the curability of the curable organopolysiloxae composition. The alkenyl group is not particularly limited, but is preferably bonded to a silicon atom.

The group bonded to the silicon atom other than the alkenyl group of component (C) is not particularly limited, and examples thereof include substituted or unsubstituted monovalent hydrocarbon groups. The examples thereof include an alkyl group, a cycloalkyl group, an aryl group, a cycloalkyl-alkyl group, an aralkyl group, and a halogenated hydrocarbon group. An alkyl group, particularly, methyl group; and aryl group, particularly, a phenyl group, are preferable. Among the T units, R is preferably an alkyl group (especially, a methyl group) or an aryl group (particularly, a phenyl group).

Component (C) may have a hydroxyl group or an alkoxy group as a group bonded to a silicon atom.

Component (C) is preferably a branched organopolysiloxane having two or more alkenyl groups in the molecule and having siloxane units (T units) represented by R³SiO_{3/2}, wherein R³ is a hydrogen atom or a substituted or unsubstituted monovalent hydrocarbon group with the exception of unsaturated groups, preferably, alkenyl groups. The alkenyl group and the group bonded to the silicon atom other than the alkenyl group are the same as described above.

The content of the alkyl group to the total amount of the groups bonded to the silicon atom (100 mol %) is not particularly limited, but is preferably from 10 to 40 mol %.

The content of the aryl group to the total amount of the groups bonded to the silicon atom (100 mol %) is not particularly limited, but is preferably from 10 to 80 mol %.

Particularly, the branched organopolysiloxane has a proportion of an aryl group (particularly, phenyl group) of not less than 20 mol %, for example, 45 to 60 mol %, based on the total amount of the groups bonded to silicon atoms (100 mol %). The sulfur barrier property of the cured product tends to be further improved. The content of the alkyl group, particularly methyl group, based on the total amount of the silicon atom-bonded groups (100 mol %), is preferably 30 mol % or more, more preferably, 40 to 70 mol %.

Meanwhile, component (C) is also preferably a branched organopolysiloxane having at least one silicon bonded alkenyl group and at least one silicon bonded aryl group per molecule, and having siloxane units represented by formula: R³SiO_{3/2} where R³ is as described above.

Examples of the aryl groups may include phenyl, tolyl, xylyl, or naphthyl group, preferably phenyl group. Examples of the substituents of hydrocarbon groups may include the above-mentioned alkyl groups, the above-mentioned alkenyl groups, the above-mentioned aryl groups, the above-mentioned aralkyl groups, or the above-mentioned halogenated alkyl groups, particularly preferably the above-mentioned alkyl groups or the above-mentioned aryl groups.

Component (C) may be in a liquid state or a solid state at 25° C.

As component (C), an organopolysiloxane represented by the average unit formula:

(R⁴₃SiO_{1/2})ₐ₂(R⁴₂SiO_{2/2})_{b2}(R⁴SiO_{3/2})_{c2}(SiO_{4/2})_{d2}(XO_{1/2})ₑ₂

is preferable.

Each of R⁴ is the same or different from each other, and is a substituted or unsubstituted monovalent hydrocarbon group, for example, an alkyl group, an alkenyl group, an aryl group, an aralkyl group, and a halogenated hydrocarbon group, as mentioned above.

However, a part of R⁴ is preferably an alkenyl group, in particular, a vinyl group, and the ratio thereof is controlled to be within a range of 1 or more, preferably 2 or more, in the molecule. For example, a content of the alkenyl group, based on the total amount of R⁴, is preferably 0.1 to 40 mol %. By controlling the proportion of the alkenyl group within the above range, the curability of the curable organopolysiloxane composition tends to be further improved. That is, when the content of the alkenyl groups is below the lower limit or exceeds the upper limit of the above-mentioned range, its reactivity tends to decrease. As R⁴ other than an alkenyl group, an alkyl group, particularly methyl group, and an aryl group, particularly, a phenyl group, are preferable.

X is a hydrogen atom or an alkyl group similarly to the above. Examples of the alkyl group include a methyl group, an ethyl group, a propyl group, a butyl group, a pentyl group and a hexyl group, particularly preferably a methyl group.

Each of a2, b2, c2, d2 and e2 is the same or different from each other, and is 0 or a positive number; and each of (a2+b2+c2) and (a2+d2) is a positive number. Preferably, b2/c2 is a number between 0 and 10, a2/c2 is a number between 0 and 0.5, d2/(a2+b2+c2+d2) is a number between 0 and 0.3, and e2/(a2+b2+c2+d2) is a number between 0 and 0.4.

The content of the alkenyl group, based on the total amount of groups bonded to silicon atoms (100 mol %), in the branched organopolysiloxane is not particularly limited, but is preferably from 0.1 to 40 mol %, from the viewpoint of curability of the curable organopolysiloxane composition.

Although there are no limitations concerning the molecular weight of component (C), when converted to standard polystyrene, its weight average molecular weight (Mw) should preferably be in the range of from 500 to 10,000, and, especially preferably, in the range of from 700 to 3,000.

In the curable silicone resin composition, component (C) may be used singly or in combination of two or more.

The content of component (C) is the balance based on the total amount of the composition wherein the composition consists of components (A), (B) and (C), optionally, together with other additives such as an adhesive promoter.

### Component (D)

Component (D) is a hydrosilylation catalyst comprising a platinum group metal.

The hydrosilylation catalyst of component (D) is used to promote the hydrosilylation between the alkenyl groups of components (A) and (C) and the hydrosily group (the silicon bonded hydrogen atoms of component (B)).

The hydrosilylation catalyst contains at least one platinum group metal selected from the group consisting of ruthenium, rhodium, palladium, platinum, osmium, and iridium. For example, a platinum catalyst, a rhodium catalyst, or a palladium catalyst can be used.

Platinum catalysts are preferable because of their ability to significantly stimulate the cure of the present composition.

Examples of the platinum catalysts include platinum fine powder, platinum black, platinum-supported silica fine powder, platinum-supported activated carbon, chloroplatinic acid, a complex of chloroplatinic acid and alcohols, aldehydes, or ketones, platinum/olefin complexes, platinum/carbonyl complexes (such as platinum-carbonylvinylmethyl complexes), platinum-vinylmethylsiloxane complexes (such as platinum-divinyltetramethyldisiloxane complexes and platinum-cyclovinylmethylsiloxane complexes), platinum-phosphine complexes, or platinum-phosphite complexes, platinum/alkenylsiloxane complexes.

The rhodium catalysts comprises rhodium instead of platinum, and the palladium catalysts comprises palladium instead of platinum, and the examples thereof are the same as those of the platinum catalysts except that rhodium or palladium is used instead of platinum.

Among them, as component (D), a platinum-based catalyst (hydrosilylation catalyst comprising platinum), in particular, platinum/alkenylsiloxane complexes or a chloroplatinic acid/an alcohol or aldehyde complex, is preferable because the reaction rate is good.

Examples of the alkenylsiloxanes include 1,3-divinyl-1,1,3,3-tetramethyldisiloxane, 1,3,5,7-tetramethyl-1,3,5,7-tetravinylcyclotetrasiloxane, alkenylsiloxanes obtained by substituting groups such as ethyl, phenyl etc. for some of the methyl groups of the above-mentioned alkenylsiloxanes, and alkenylsiloxanes obtained by substituting groups such as allyl, hexenyl, etc. for the vinyl groups of the above-mentioned alkenylsiloxanes.

1, 3-divinyl-1,1,3,3-tetramethyldisiloxane is particularly preferable because of the excellent stability of the platinum/alkenylsiloxane complex. Also, due to the improvement in the stability of the complex that their addition may bring, it is desirable to add 1,3-divinyl-1, 1,3,3-tetramethyldisiloxane, 1,3-diallyl-1,1,3,3-tetramethyldisiloxane, 1,3-divinyl-1,3-dimethyl-1,3-diphenyldisiloxane, 1,3-divinyl-1,1,3,3-tetraphenyldisiloxane, 1,3,5, 7-tetramethyl-1,3,5, 7-tetravinylcyclotetrasiloxane and other alkenylsiloxanes and organosiloxane oligomers such as dimethylsiloxane oligomers to the platinum/alkenylsiloxane complex, with alkenylsiloxanes being particularly preferable.

In the curable organopolysiloxane composition, component (D) may be used singly or in combination of two or more kinds.

There are no limitations on the content of component (D) as long as the amount promotes curing of the curable organopolysiloxane composition. However, the content of component (D) in the composition is preferably 1×10⁻⁸ to 1×10⁻² mole (per 1 mole) of the alkenyl group contained in the composition, and more preferably 1.0×10⁻⁶ to 1.0×10⁻³ mol. When the content of component (D) is 1×10⁻² mol or more, the cured product tends to be formed more efficiently. On the other hand, when the content of component (D) is 1×10⁻² mol or less, a cured product having a better color (less coloring) tends to be obtained.

The content of component (D) in the composition is not particularly limited. For example, the content of the platinum group metal in the hydrosilylation catalyst is preferably in an amount of from 0.0001 to 5 parts by weight, relative to 100 parts by weight of the total of components (A), (B), and (C), optionally along with other additives. This is due to the fact that when the content of component (D) is below the lower limit of the above-mentioned range, the present composition tends to fail to completely cure, and, on the other hand, when it exceeds the upper limit of the above-mentioned range, problems may arise in imparting various colors to the resultant cured product. When the content of component (D) is within this range, a cured product can be formed more efficiently and a cured product having a better color tends to be obtained.

The curable organopolysiloxane composition of the present invention may further comprise other components, generally used in this field, for example, a curing inhibitor; a phosphor; silica, glass, alumina, zinc oxide and other inorganic fillers; micropowders of organic resins such as polymethacrylate resin; heat-stabilizers, dyes, pigments, flame retardants, solvents, etc. as optional components, so long as this does not impair the purpose of this invention. An adhesive promoter may also be comprised in the composition. The other components are preferably present in an amount of 1 to 10% by weight, more preferably, 1.5 to 5% by weight, based on the total amount of the composition.

The compositions described above may be prepared by mixing the components generally used in this art, for example, by mixing all the components at ambient temperature.

An LED encapsulant of the present invention comprises the curable organopolysiloxane composition as described above. Encapsulation for light emitting devices in the present invention is well known to the art and may be used in the present invention. For example, prise casting, dispensing, molding may be used.

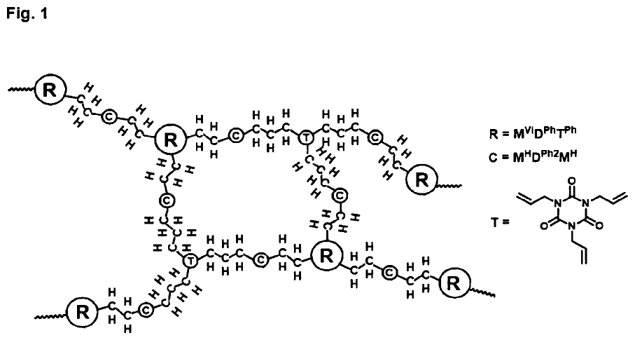

FIG. 1 represents one example of the crosslinked structure of the curable silicone resin composition according to the present invention. In FIG. 1, T represents isocyanurate represented by Formula 3 below as component (A), C represents M^{H}D^{Ph2}M^{H} as component (B), and R represents M^{Vi}D^{Ph}T^{Ph} as component (C).

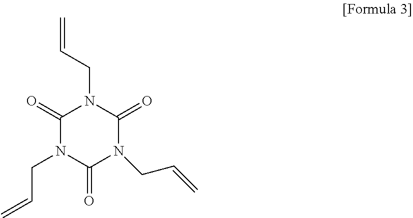 [SMILES: C=CCn1c(=O)n(CC=C)c(=O)n(CC=C)c1=O]

As shown in FIG. 1, vinyl group of T makes a bonding with siloxane. Therefore, vinyl group is more preferable to epoxy group.

In a semiconductor device of the present invention, semiconductor elements are coated with a cured product of the curable organopolysiloxane composition as described above. Such semiconductor elements are exemplified by semiconductor elements used in diodes, transistors, thyristors, solid-state image pickup elements, monolithic ICs and in hydride ICs. In particular, it is preferable that semiconductor elements are light-emitting elements.

Examples of such semiconductor devices included diodes, light-emitting diodes, transistors, thyristors, photocouplers, CCDs, monolithic IICs, hybrid ICs, LSIs, and VLSIs.

The invention will now be illustrated by examples, which are not to be construed as limiting the invention in any way.

### Synthesis Examples 1 to 2 (Synthesis of Siloxane Compound)

### 1. Synthesis Example 1: Synthesis of Hydrogensiloxane Single Molecule Compound

500 g of a mixed solvent, which is prepared by mixing water and toluene at a weight ratio of 1:9, was charged in a three-necked flask. While maintaining the temperature at 23° C., as a monomer, a mixture comprising methylchlorosilane and diphenyldichlorosilane at a molar ratio of 2:1 was added into the flask over 30 minutes. After completion of the addition, condensation was carried out while refluxing at 30° C. for 1 hour. Then, after cooling the flask to room temperature, water layer was removed to prepare a solution in which the resulting condensed compound was dissolved in toluene. The resultant solution was washed with water to remove chlorine as a by-product. Subsequently, the neutral solution was distilled under reduced pressure. Toluene was removed. Finally, a siloxane compound represented by formula as below was obtained.

(HMe₂SiO_{1/2})_{0.67}(Ph₂SiO_{2/2})_{0.33}

### 2. Synthesis Example 2: Synthesis of T-structure Organovinylpolysiloxane Compound

1 kg of a solvent, which is prepared by mixing water and toluene at a weight ratio of 1:9, was charged into a three-necked flask. While maintaining the temperature at 23° C., as a monomer, a mixture comprising vinyldimethylchlorosilane, methylphenyldichlorosilane and phenyltrichlorosilane at a molar ratio of 2:1:7 was added. After completion of the addition, condensation was carried out while refluxing at 90° C. for 3 hours. Then, after cooling the flask to room temperature, water layer was removed to prepare a solution in which the resulting condensed compound was dissolved in toluene. The resultant solution was washed with water to remove chlorine as a by-product. Subsequently, the neutral solution was distilled under reduced pressure. Toluene was removed. Finally, a siloxane compound represented by formula as below was obtained.

(Me₂ViSiO_{1/2})_{0.2}(MePhSiO_{2/2})_{0.1}(PhSiO_{3/2})_{0.7}

### Synthesis Examples 3 to 7 (Synthesis of Isocyanate)

### 1. Synthesis Example 3: Synthesis of Isocyanurate Compound

250 g of water and propenol (3 mol) were added to a three-necked flask. And isocyanuric acid (1 mol) was slowly added thereto while maintaining the pH at 6.5 to 7.5 and the temperature at 65° C. After completion of the addition, condensation was carried out while heating the flask to reflux at 80° C. for 7 hours. Subsequently, the reaction product was cooled to 10° C., and ethanol and DMSO were added to the reaction product to obtain a solid. The solid obtained was filtered to obtain a precipitated solid. The resulting precipitated solid was washed with acetone several times.

Subsequently, the resulting reaction product was subjected to distillation under reduced pressure to remove the residual solvent to obtain 1, 3, 5-tripropen-1-yl-triazine-2, 4, 6(1H, 3H, 5H)-trione compound represented by formula 3 as below was obtained.

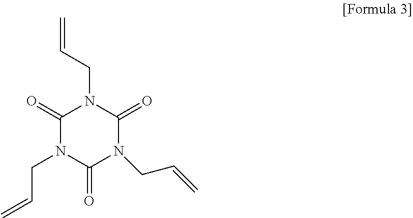 [SMILES: C=CCn1c(=O)n(CC=C)c(=O)n(CC=C)c1=O]

### 2. Synthesis Example 4: Synthesis of Isocyanurate Compound

In the same manner as Synthesis Example 3 except that 2-methyl-2-propenol (3 mol) was used instead of propenol (3 mol), 1, 3, 5-tris(2-methyl-2-propenyl)-triazine-2,4,5(1H, 3H, 5H)-trion represented by formula 4 as below was obtained.

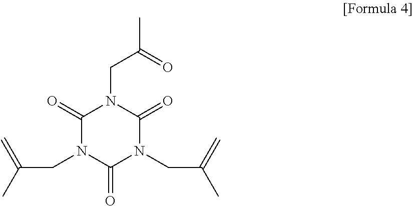 [SMILES: C=C(C)Cn1c(=O)n(CC(=C)C)c(=O)n(CC(C)=O)c1=O]

### 3. Synthesis Example 5: Synthesis of Isocyanurate Compound

In the same manner as Synthesis Example 3 except that 2-oxiranylmethanol (1 mol) and propenol (2 mol) were used instead of propenol (3 mol), 1-(2-oxiranylmethyl)-3,5-di-(2-propen-1-yl)-triazine-2,4,6(1H, 3H, 5H)-trion represented by formula 5 as below was obtained.

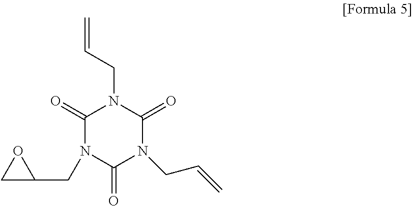 [SMILES: C=CCn1c(=O)n(CC=C)c(=O)n(CC2CO2)c1=O]

### 4. Synthesis Example 6: Synthesis of Isocyanurate Compound

In the same manner as Synthesis Example 3, except that benzyl alcohol (1 mol) and propenol (2 mol) were used instead of propenol (3 mol), 1-benzyl-3,5-di-(2-propen-1-yl)-triazine-2,4,6(1H, 3H, 5H)-trion represented by formula 6 as below was obtained.

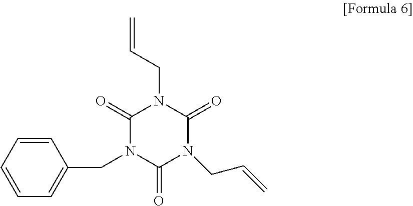 [SMILES: C=CCn1c(=O)n(CC=C)c(=O)n(Cc2ccccc2)c1=O]

### 5. Synthesis Example 7: Synthesis of Isocyanurate Compound

In the same manner as Synthesis Example 3, except that 2,3-dibromopropanol (1 mol) and propenol (2 mol) were used instead of propenol (3 mol), 1-(2,3-dibromopropyl)-3,5-di-(2-propen-1-yl)-triazine-2,4,6(1H, 3H, 5H)-trion represented by formula 7 as below was obtained.

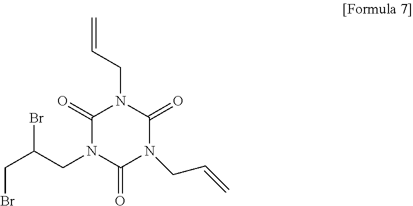 [SMILES: C=CCn1c(=O)n(CC=C)c(=O)n(CC(Br)CBr)c1=O]

### Example 1 (Preparation of Encapsulant Composition)

The organohydrogensiloxane compound obtained in Synthesis Example 1, the organopolysiloxane compound having the DT structure obtained in Synthesis Example 2, and the isocyanurate compound represented by formula 3 obtained in Synthesis Example 3 were mixed at the weight ratio as shown in Table 1 below.

2.5 weight % of glycidoxy functionalized polysiloxane as an adhesive promoter, based on the total weight of each mixture, and 5 ppm of a hydrosilylation catalyst Pt-CS 2.0 (manufactured by Unicore) based on the total weight of each mixture, were added to the above mixture.

And then the resulting product was vacuumed and defoamed to prepare the encapsulant compositions according to Example 1.

### Example 2 (Preparation of Encapsulant Composition)

In the same manner as Example 1 except that the compound represented by formula 4 obtained in Synthesis Example 4 was used instead of the compound represented by formula 3 obtained in Synthesis Example 3, as shown in Table 1 below, the encapsulant composition according to Example 2 was prepared.

### Examples 3 to 5 (Preparation of Encapsulant Composition)

In the same manner as Example 1 except that the compound represented by formulae 5, 6, and 7, respectively, obtained in Synthesis Example 5, 6, and 7, was used instead of the compound represented by formula 3 obtained in Synthesis Example 3, as shown in Table 1 below, the encapsulant composition according to Examples 3, 4, and 5 was prepared.

### Comparative Example 1 (Preparation of Encapsulant Composition)

In the same manner as Example 1 except that organocyclicsiloxane compound represented by formula 8 as below was used instead of the compound represented by formula 3 obtained in Synthesis Example 3, as shown in Table 1, the encapsulant composition according to Comparative Example 1 was prepared.

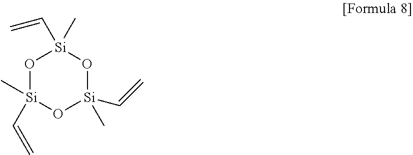

### Comparative Example 2 (Preparation of Encapsulant Composition)

In the same manner as Example 1 except that isocyanurate compound represented by formula 9 as below was used instead of the compound represented by formula 3 obtained in Synthesis Example 3, as shown in Table 1, the encapsulant composition according to Comparative Example 2 was prepared.

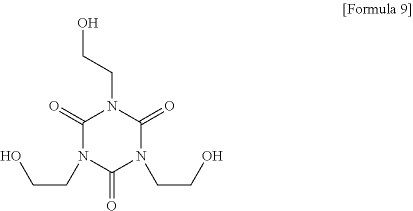 [SMILES: O=c1n(CCO)c(=O)n(CCO)c(=O)n1CCO]

TABLE 1

| | | | | | | Comp. | Comp. |
|---|---|---|---|---|---|---|---|
| | Example 1 | Example 2 | Example 3 | Example 4 | Example 5 | Example 1 | Example 2 |
| Hydrogen- | 22.5 | 22.5 | 22.5 | 22.5 | 22.5 | 22.5 | 22.5 |
| siloxane | | | | | | | |
| Organovinyl- | 70 | 70 | 70 | 70 | 70 | 70 | 70 |
| polysiloxane | | | | | | | |
| Organocyclic- | — | — | — | — | — | 5 | — |
| siloxane | | | | | | formula 8 | |
| Isocyanurate | 5 | 5 | 5 | 5 | 5 | — | 5 |
| | formula 3 | formula 4 | formula 5 | formula 6 | formula 7 | — | formula 9 |
| Adhesive | 2.5 | 2.5 | 2.5 | 2.5 | 2.5 | 2.5 | 2.5 |
| Promoter | | | | | | | |
| Catalyst (ppm) | 5 | 5 | 5 | 5 | 5 | 5 | 5 |

(Unit of each components: % by weight except that the unit of catalyst is ppm based on the total amount of the composition.)

### Experimental Examples

The hardness and refractive index of the encapsulant composition prepared above were measured as described below.

Each composition was made to an encapsulant by curing it at 150° C. for 4 hours and then hardness (shore D), modulus (at 125° C. CMPa), thermal shock property, moisture permeability, oxygen permeability, and yellow reliability of each encapsulant were measured as described below.
Refractive Index: Refractive Index of the liquid mixture before curing was measured under D-line (589 nm) wavelength by using an Abbe refractive index meter.
Hardness: The polysiloxane composition of Examples 1 to 5 and Comparative Examples 1 and 2 was added into a Teflon coated mold (4 cm (width)×15 cm (length)×6 mm (thickness)), was cured at 150° C. for 4 hours, and cooled to room temperature. Then, hardness was measured with a Shore D hardness tester.
Modulus: The polysiloxane composition of Examples 1 to 5 and Comparative Examples 1 and 2 was added into a Teflon coated mold (5 cm (width)×5 cm (length)×4 mm (thickness)), cured at 150° C. for 4 hours, and cooled to room temperature. Then, modulus at 125° C. was measured with dynamic mechanical analysis (DMA) apparatus by raising the temperature from −50° C. to 150° C. at a heating rate of 2° C./min.
Thermal shock test: The polysiloxane compositions according to Examples 1 to 5, Comparative Examples 1 and 2 and YAG fluorescent material were charged in an LED PKG (5050 PKG), cured at 150° C. for 4 hours, and cooled to room temperature to prepare package samples. Subsequently, the package was exposed under the following conditions for 500 cycles wherein exposure under the following condition for following time is regarded as one cycle. After 500 cycles, the package sample was taken out and tested for operation. The amount of package that did not work was recorded.

Conditions: Two chambers were maintained at −45° C. and 125° C. respectively. The package was exposed to low temperature condition of −45° C. for 15 minutes and high temperature condition of −125° C. for 15 minutes, while moving back and forth between the two chambers.
Water Moisture Permeability and Oxygen Permeability: A 1 mm thick film was produced using a mold and cured at 150° C. for 4 hours. Water moisture permeability and oxygen permeability were measured according to ASTM F-1249/ASTM D-3985.
Yellowing reliability: Yellow reliability was measured in the following manner.
(I) The prepared mixture for encapsulating material is weighed and mixed with a phosphor in a beaker, followed by defoaming.
(II) The mixed resin and phosphor were applied in the LED package.
(III) The package applied was placed in a curing oven and cured. (150° C.×4 hr)
(IV) After completion of curing, the cured package was cooled to room temperature. Then the initial brightness of the package was measured.
(V) A sulfur mixture consisting of 0.7 g of K2S and 50 g of H₂O was added to a 250 ml glass bottle and place the package assembled on top of the glass bottle not to contact with sulfur mixture.
(VI) A package and a glass bottle containing sulfur were added in a 70° C. water bath. Sulfur infiltration assessments were performed after 0 hour, and 8 hours. After measuring 5 packages, the average value was recorded.
(VII) The final result is calculated as the reduction rate of the luminance value after 8 hours relative to the initial luminance value.

The results of the experiments are shown in Table 2 below.

TABLE 2

| | | | | | | Comp. | Comp. |
|---|---|---|---|---|---|---|---|
| | Example 1 | Example 2 | Example 3 | Example 4 | Example 5 | Example 1 | Example 2 |
| Bonding agent | 2.5 | 2.5 | 2.5 | 2.5 | 2.5 | 2.5 | 2.5 |
| Catalyst (ppm) | 5 | 5 | 5 | 5 | 5 | 5 | 5 |
| Appearance | transparent | transparent | transparent | transparent | transparent | transparent | transparent |
| Curing | 150° C., 4 hours | | | | | | |
| Condition | | | | | | | |
| Refractive | 1.55 | 1.55 | 1.55 | 1.55 | 1.55 | 1.53 | 1.53 |
| Index | | | | | | | |
| Hardness | 60 | 60 | 60 | 60 | 60 | 60 | 50 |
| Modulus | 2.5 | 2.1 | 1.8 | 2.1 | 2.3 | 4.1 | 1.4 |
| (@125° C., | | | | | | | |
| MPa) | | | | | | | |
| Thermal shock | 100/100 | 100/100 | 100/100 | 100/100 | 100/100 | 45/100 | 0/100 |
| test | | | | | | | (crack) |
| (Operation | | | | | | | |
| quantity after | | | | | | | |
| 500 cycle) | | | | | | | |
| Yellow | 81.2 | 76.3 | 77.1 | 73.1 | 71.1 | 65.4 | 68 |
| reliability (%) | | | | | | | |
| Moisture | 9.8 | 10.6 | 10.2 | 11.2 | 10.9 | 12.4 | 14.7 |
| permeability | | | | | | | |
| (gm/m² day) | | | | | | | |
| Oxygen | 487 | 512 | 511 | 525 | 555 | 584 | 653 |
| permeability | | | | | | | |
| (cc/m² day) | | | | | | | |

(The content of each component is % by weight.)

As shown in Table 2, the compositions according to Examples 1 to 5 including the compounds represented by formulae 3 to 7 shows the modulus reduction effect and the normal working feature even after the thermal shock test.

Meanwhile, the composition of comparative Example 1, which has no isocyanurate structure, shows a high modulus, a high defect rate in the thermal shock test, and a low moisture permeability, oxygen permeability and yellow reliability, when compared with the composition according to Examples 1 to 5.

In the composition according to Comparative Example 2, which contains isocyanurate, but has no alkenyl structure, the curing reaction between isocyanurate and silicon does not occur during the curing reaction. As a result, the hardness of the cured product itself is low, and thus its high temperature modulus are low, but the thermal shock property is reduced due to the presence of unreacted water in the cured product.

In the case of such composition containing isocyanurate having alkenyl, as in the examples, mechanical properties such as hardness are improved, which provides thermal stability and low moisture and oxygen permeability as well as good appearance. Thus, the encapsulant obtained from the composition may have an effect of reducing entry of external containments after curing.

1.-14. (canceled)

15. A curable organopolysiloxane composition, comprising:
(A) at least one compound of the formula 1 below and having molecular weight less than 500, g/mol 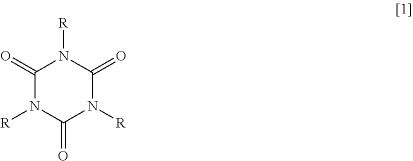
(B) at least one organopolysiloxane of the formula 2: 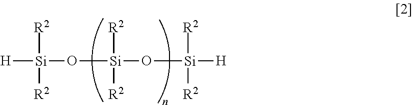
where R² each is the same as or different and is hydrogen or a substituted or unsubstituted monovalent hydrocarbon group, excluding unsaturated groups,
n is an integer in the range of from 1 to 20, and
(C) at least one polysiloxane compound having at least one Si-bonded alkenyl group,
wherein R represents hydrogen, substituted or unsubstituted C1 to C20 alkyl, substituted or unsubstituted C7 to C20 arylalkyl, substituted or unsubstituted C1 to C20 heteroalkyl, substituted or unsubstituted C3 to C12 cycloalkyl, substituted or unsubstituted C2 to C20 heterocycloalkyl, substituted or unsubstituted C2 to C20 alkenyl, substituted or unsubstituted C2 to C20 alkynyl, substituted or unsubstituted C6 to C30 aryl, substituted or unsubstituted C1 to C10 alkoxy, substituted or unsubstituted C1 to C30 acyl, hydroxy, halogen, or a combination thereof, provided that at least one of R is substituted or unsubstituted C2 to C20 alkenyl, and
wherein the amount of component(s) (A) is in the range of 1 to 20% by weight, the amount of component(s) (B) is in the range of 15 to 30% by weight, and the amount of component(s) (C) is the balance of the total amounts of (A), (B), and (C).

16. The curable organopolysiloxane composition of claim 15, further comprising:
(D) a hydrosilylation catalyst comprising a platinum group metal.

17. The curable organopolysiloxane composition of claim 15,
wherein at least two R's in component (A) are substituted or unsubstituted C2 to C20 alkenyl.

18. The curable organopolysiloxane composition of claim 15, wherein,
at least one component (C) is an organopolysiloxane comprising siloxane units of average unit formula R³SiO_{3/2} where R³ is a substituted or unsubstituted monovalent hydrocarbon group.

19. The curable organopolysiloxane composition of claim 15, wherein component (C) is an organopolysiloxane with the average unit formula:
(R⁴₃SiO_{1/2})ₐ₂(R⁴₂SiO_{2/2})_{b2}(R⁴SiO_{3/2})_{c2}(SiO_{4/2})_{d2}(XO_{1/2})ₑ₂
where each R⁴ is the same different, and each is selected from the group consisting of alkyl, alkenyl, aryl, aralkyl, and halogenated hydrocarbon groups,
X is hydrogen or an alkyl group,
each of a2, b2, c2, d2 and e2 is the same or different, and is 0 or a positive number, and
each of (a2+b2+c2) and (a2+d2) is a positive number.

20. The curable organopolysiloxane composition of claim 15, wherein
at least two R's are substituted or unsubstituted C2 to C6 alkenyl.

21. The curable organopolysiloxane composition of claim 15, wherein
the molar ratio of hydrosilyl groups in component (B) to alkenyl groups in component (C) is 1 to 1.2.

22. A cured product obtained by curing the curable organopolysiloxane composition of claim 15.

23. An LED encapsulant, comprising the curable organopolysiloxane composition of claim 15.

24. A semiconductor device, in which semiconductor elements are coated with a cured product of the curable organopolysiloxane composition of claim 15.

25. The semiconductor device of claim 24, wherein said semiconductor elements comprise light-emitting elements.
